(19) United States
(12) Patent Application Publication
(10) Pub. No.: US 2009/0015995 A1
(43) Pub. Date: Jan. 15, 2009

(54) COMBINATORIAL KEYBOARD STRUCTURE WITH UPRIGHT STANDING ABILITY

(76) Inventor: Chih-Lang Lin, Taipei City (TW)

Correspondence Address: WPAT, PC, 7225 BEVERLY ST., ANNANDALE, VA, 22003, US

(21) Appl. No.: 11/852,770

(22) Filed: Sep. 10, 2007

(30) Foreign Application Priority Data
Jul. 10, 2007 (TW) 096124998

(51) Int. Cl. G06F 1/16; H05K 5/00; H05K 7/00

(52) U.S. Cl. 361/680

(57) ABSTRACT

A combinatorial keyboard structure with upright standing ability is disclosed, which comprises: a plurality of keypads, each being configured with at least a signal transmitting device, a first connecting mechanism being arranged at the bottom thereof, and at least a second connecting mechanism being arranged at a side thereof; and a base, being a plate-like element with a dented space formed therein; wherein, an upright standing keyboard unit is formed by connecting the first connecting mechanism of one of the plural keypads with that of another keypad, and thus an upright standing keyboard structure is constructed by sequentially connecting the second connecting mechanisms of more than one so-formed upright standing keyboard units from one to another while enabling the so-constructed upright standing keyboard structure to be fitted into the dented space of the base; and a keyboard structure is constructed by sequentially connecting the second connecting mechanisms of the plural keypads from one to another.

### FIELD OF THE INVENTION

The present invention relates to a combinatorial keyboard structure with upright standing ability, and more particularly, to a keyboard structure that is constructed as an assembly of a plurality of upright standing keypads so as to be used as a handheld device.

### BACKGROUND OF THE INVENTION

With rapid advance of technology as well as our quest for an ever increasing quality of life, we are no longer satisfied with an input device just for its good inputting function. Nowadays, a good input device must have a soft touch, good ergonomic and user-friendly designs, and so on.

A conventional QWERTY keyboard structure usually laid all its keys flatly and horizontally on a plate-like base with different groupings respectively specified for alphabet keys, number keys, directional keys and function keys. Nevertheless, it is also common to see a conventional keyboard having divided alphabet section, as that shown in FIG. 1. It is noted that although such keyboard configuration with divided alphabet section is more efficient with regard to hand movement, such design is not beneficiary for portability and carrying since such design will result the keyboard structure to have larger size and weight. In those external keyboard structures for portable electronic devices, foldable design is commonly used. However, when such foldable external keyboard is folded, the keys will collide and wear with each other that are easily damaged. And last but not least, the poor key configuration of conventional QWERTY keyboard structure will cause tension and stiff to our wrist and joints when a person types on such conventional QWERTY keyboard structure for a long period of time. In the mean time, as such conventional QWERTY keyboard structure is usually bulky that is not ease to move around, a typist is common to adjust one's gesture to match with the poor key configuration, regional bone and muscle fatigue or even damage are inevitable.

### SUMMARY OF THE INVENTION

In view of the disadvantages of prior art, the primary object of the present invention is to provide a combinatorial keyboard structure with upright standing ability, capable of operating as a handheld device with having to accommodating one's gesture for the poor key configuration as that commonly seen in conventional QWERTY keyboard structure.

To achieve the above object, the present invention provide a combinatorial keyboard structure with upright standing ability, which comprises: a plurality of keypads, each being configured with at least a signal transmitting device, a first connecting mechanism being arranged at the bottom thereof, and at least a second connecting mechanism being arranged at a side thereof; and a base, being a plate-like element with a dented space formed therein; wherein, an upright standing keyboard unit is formed by connecting the first connecting mechanism of one of the plural keypads with that of another keypad, and thus an upright standing keyboard structure is constructed by sequentially connecting the second connecting mechanisms of more than one so-formed upright standing keyboard units from one to another while enabling the so-constructed upright standing keyboard structure to be fitted into the dented space of the base; and a keyboard structure is constructed by sequentially connecting the second connecting mechanisms of the plural keypads from one to another.

Preferably, a hidden supporting part is disposed at the bottom of each keypad to be used for elevating the height of the keyboard structure as the plural keypads is being assembled as such.

Preferably, the signal transmitting device is a device selected from the group consisting of a USB device and a PS2 device.

Preferably, the signal transmitting device is enabled to link the plural keypads with one another.

Preferably, there is only one single keypad selected from the plural keypads that is configured with a signal transmitting device not only capable of communicating with those of the other keypads, but also with a prime.

Preferably, the base is further comprised of a fixing part to be used for fixedly securing the upright standing keyboard structure to the dented space of the base.

In a preferred embodiment, the keyboard structure is composed of: a keyboard unit being formed by sequentially connecting the second connecting mechanisms of three keypads from one to another; and one independent keypad.

Preferably, the keyboard unit is connected with the independent keypad by a transmission line.

Preferably, the keyboard structure is composed of: two keyboard units, each being formed by sequentially connecting the second connecting mechanisms of two keypads from one to another.

Preferably, the two keyboard units are connected by the use of a transmission line.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 shows a conventional QWERTY keyboard structure with divided alphabet section.

FIG. 2 is a schematic view of a conventional foldable keyboard structure.

FIGS. 3A, 3B, 3C, and 3D respectively show a top view and a side view of different keypads being used for assembling a combinatorial keyboard structure of the invention.

FIG. 4 is a schematic diagram showing a base according to an exemplary embodiment of the invention.

FIGS. 5A, 5B and 5C show different assembling stages of a combinatorial keyboard structure as it is being assembled to be an upright standing keyboard structure.

FIGS. 6A and 6B show different assembling stages of a combinatorial keyboard structure as it is being assembled to be a keyboard structure.

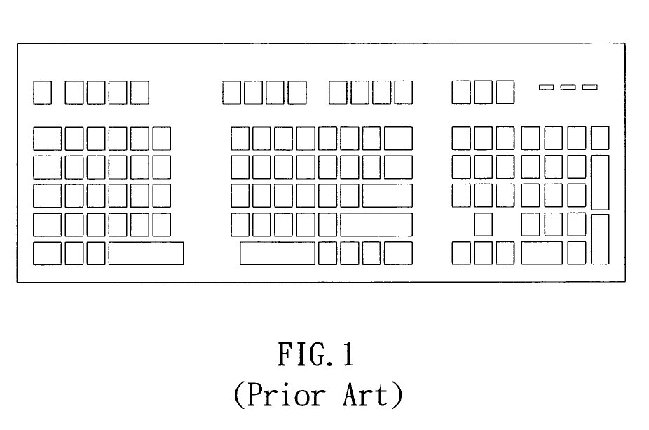

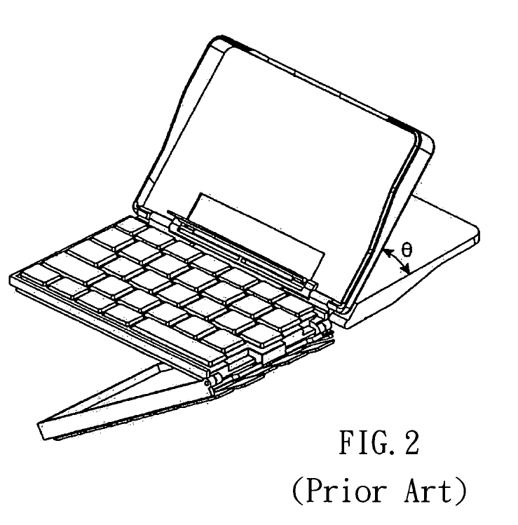

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

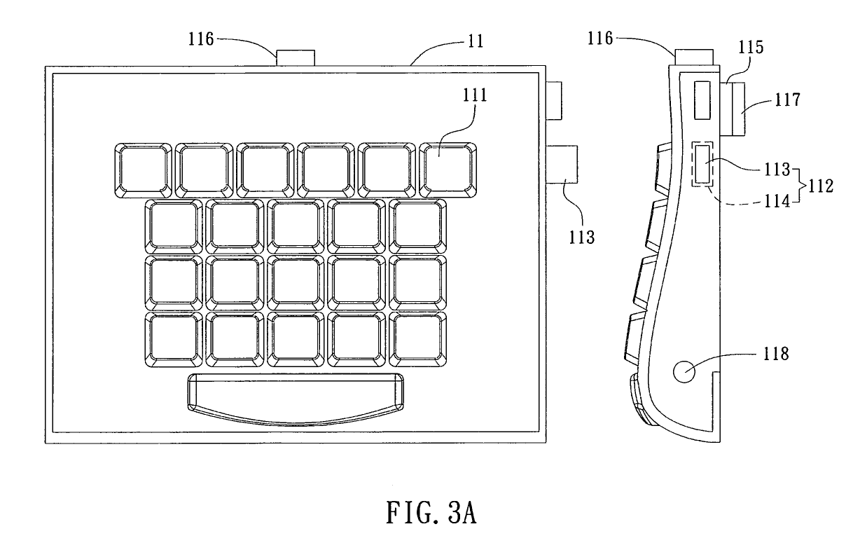

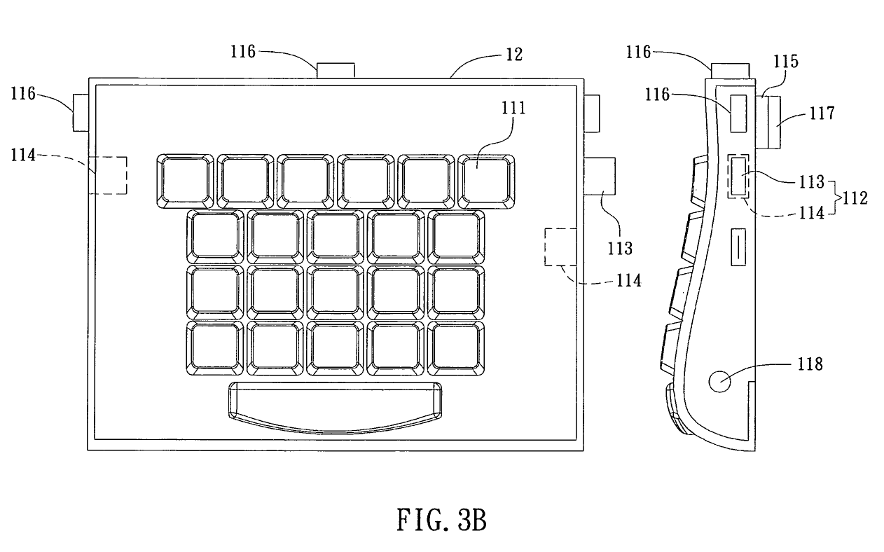

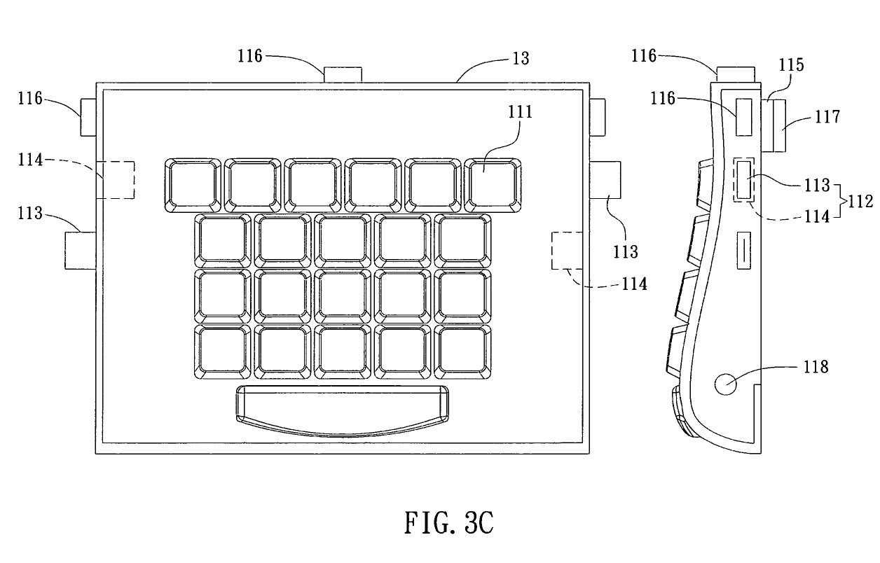

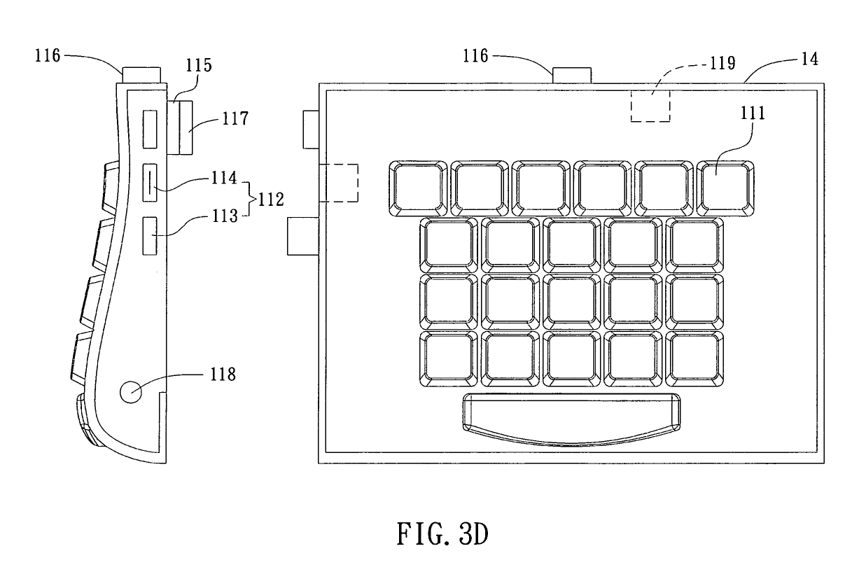

Please refer to FIG. 3A˜FIG. 3D, which respectively show a top view and a side view of different keypads being used for assembling a combinatorial keyboard structure of the invention. In this exemplary embodiment, the combinatorial keyboard structure is composed of four keypads 11, 12, 13, 14, respectively shown in FIG. 3A˜FIG. 3D, and each keypad is configured with a plurality of keys 111 that can be divided into alphabet keys, number keys, directional keys and function keys. It is noted that those alphabet keys are disposed as a conventional QWERTY keyboard while others can be arranged according to the preferences of manufacturers. In each keypad, there is at least a signal transmitting device being arranged therein, and there is only one keypad selected from the four keypads that is configured with one additional signal connection port 119 to be used for transmitting signal to a prime, as that shown in FIG. 3D. Preferably, the signal transmitting device can be a wireless communication device or a wired communication device. If a wired communication device is used as the signal transmitting device, it is necessary to be composed of an interface 113 and a connection port 114, both being arranged at its corresponding keypad. The interface 113 can be a PS2 interface or a USB interface. Moreover, each keypad is comprised of: at least a first connecting mechanism 115, being arranged at the bottom thereof; and at least a second connecting mechanism 116, being arranged at a side thereof. In which, both the first and the second connecting mechanisms can be a latch structure, or can be any connecting mechanism specialized designed by the manufacturers. In addition, there is a retractable supporting part 117 being disposed at the bottom of each keypad, while there is a fixation hole formed at a side of each keypad also.

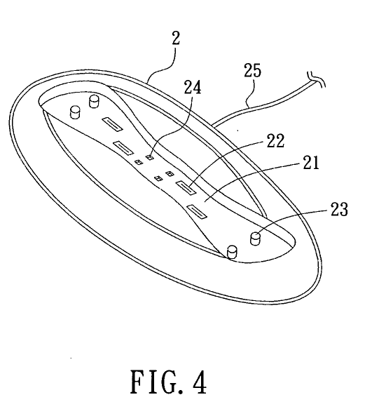

Please refer to FIG. 4, which is a schematic diagram showing a base according to an exemplary embodiment of the invention. The base 2 of FIG. 4 is a plate-like element with a dented space 21 formed therein, that the dented space is configured for receiving an upright standing keyboard and is embedded with a plurality of connection port 22, a plurality of fixation pillars 23 for securing the upright standing keyboard on the base 2, and a plurality of sockets 24 for the second connecting mechanisms to wedged therein. Moreover, the base is configured with a signal transmitting device 25 to be used for connecting the base 2 to a prime, which can be a wireless communication device or a wired communication device.

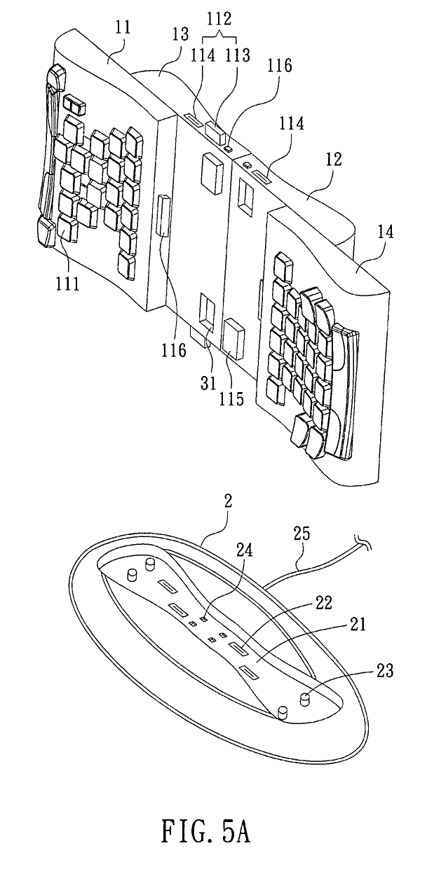

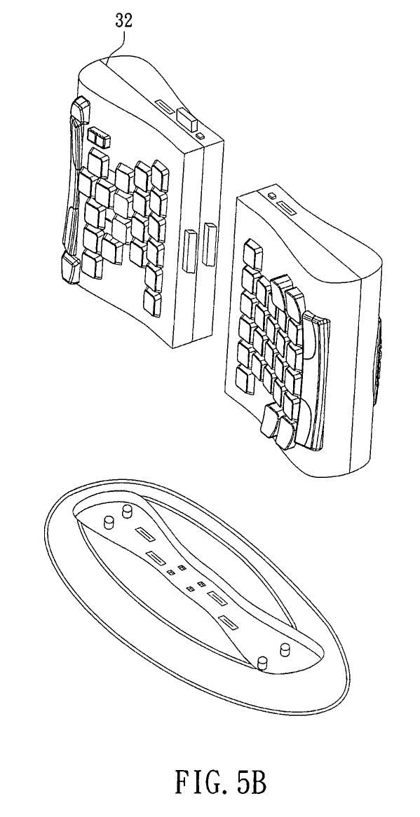

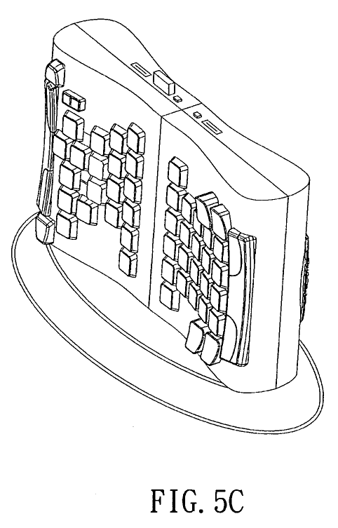

Please refer to FIGS. 5A, 5B and 5C, which show different assembling stages of a combinatorial keyboard structure as it is being assembled to be an upright standing keyboard structure. As shown in the figures, each keypad is comprised of: a first connecting mechanism 115, being arranged at the bottom thereof; and a second connecting mechanism 116, being arranged at a side thereof. By snap-fitting the first connecting mechanism 115 of one keypad into a fixation hole 31 of another keypad while fitting the first connecting mechanism 115 of that another keypad into the fixation hole 31 of the one keypad, an upright standing keyboard unit 32 can be constructed. Moreover, by connected the second connecting mechanisms 116 of two such upright standing keyboard units 32, an upright standing keyboard structure can be constructed, which can be plugged into the base 2 and thus is connected to the prime. It is noted that the signal transmitting device embedded in the base 2 can be a wireless communication device.

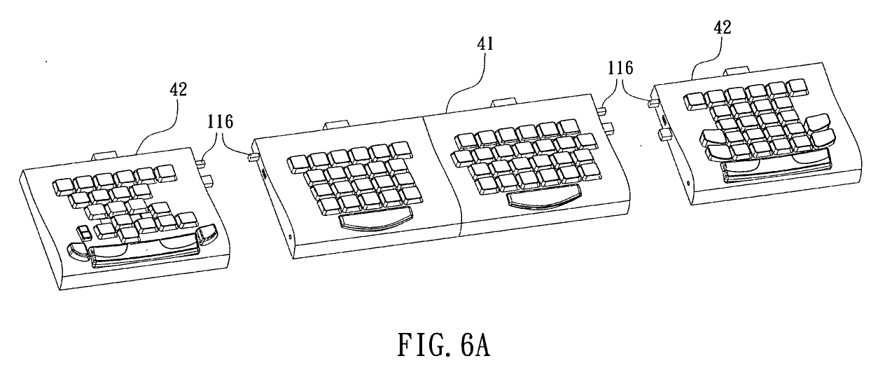

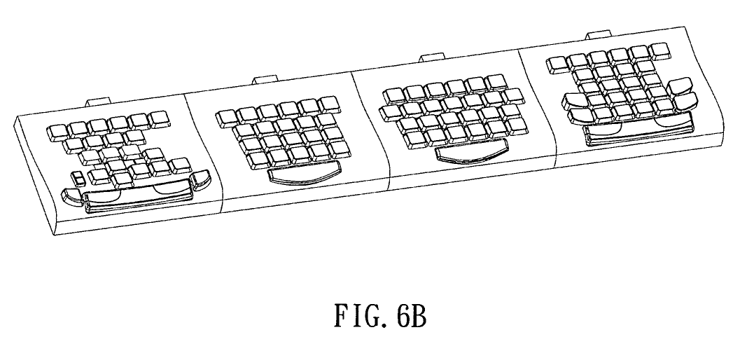

Please refer to FIGS. 6A and 6B, which show different assembling stages of a combinatorial keyboard structure as it is being assembled to be a keyboard structure. As there is at least a second connecting mechanism being disposed at a side of each keypad while each keypad is configured with at least a signal transmitting device, a keyboard structure can be constructed by sequentially connecting the second connecting mechanisms of the plural keypads from one to another. Moreover, it is possible to construct a keyboard structure which is composed of: a keyboard unit 41 of at least two connecting keypads; and at least an independent keypad 42 For instance, one combinatorial keyboard structure can be composed of: a keyboard unit being formed by sequentially connecting the second connecting mechanisms of three keypads from one to another; and one independent keypad, or can be composed of: two keyboard units, each being formed by sequentially connecting the second connecting mechanisms of two keypads from one to another. It is noted that such keyboard unit is connected to the independent keypad by a transmission line, and that is also the same for the two keyboard units. Similarly, in each keypad, there is at least a signal transmitting device being arranged therein, and there is only one keypad selected from the plural keypads of the combinatorial keyboard structure that is configured with one additional signal transmitting device to be used for transmitting signal to a prime, while the additional signal transmitting device can be a wireless communication device or a common wired communication device.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A combinatorial keyboard structure with upright standing ability, comprising:
a plurality of keypads, each being configured with at least a signal transmitting device, at least a first connecting mechanism being arranged at the bottom thereof, and at least a second connecting mechanism being arranged at a side thereof;
wherein, the first connecting mechanisms of the plural keypads are connectable with one another; the second connecting mechanisms of the plural keypads are connectable with one another.

2. The combinatorial keyboard structure of claim 1, wherein both the first connecting mechanism and the second connecting mechanism are constructed as latch structures.

3. The combinatorial keyboard structure of claim 1, wherein the signal transmitting device is a device selected from the group consisting of a wired communication device and a wireless communication device.

4. The combinatorial keyboard structure of claim 1, wherein the wired communication device is a device selected from the group consisting of a USB device and a PS2 device.

5. The combinatorial keyboard structure of claim 1, wherein the signal transmitting device is enabled to link the plural keypads with one another.

6. The combinatorial keyboard structure of claim 1, wherein there is only one single keypad selected from the plural keypads that is configured with a signal transmitting device not only capable of communicating with those of the other keypads, but also with a prime.

7. A combinatorial keyboard structure with upright standing ability, comprising:
a plurality of keypads, each being configured with at least a signal transmitting device, a first connecting mechanism being arranged at the bottom thereof, and at least a second connecting mechanism being arranged at a side thereof; and
a base, being a plate-like element with a dented space formed therein;
wherein, an upright standing keyboard unit is formed by connecting the first connecting mechanism of one of the plural keypads with that of another keypad, and thus an upright standing keyboard structure is constructed by sequentially connecting the second connecting mechanisms of more than one so-formed upright standing keyboard units from one to another.

8. The combinatorial keyboard structure of claim 7, wherein both the first connecting mechanism and the second connecting mechanism are constructed as latch structures.

9. The combinatorial keyboard structure of claim 7, wherein the signal transmitting device is a device selected from the group consisting of a wired communication device and a wireless communication device.

10. The combinatorial keyboard structure of claim 7, wherein the wired communication device is a device selected from the group consisting of a USB device and a PS2 device.

11. The combinatorial keyboard structure of claim 7, wherein the signal transmitting device is enabled to link the plural keypads with one another.

12. The combinatorial keyboard structure of claim 7, wherein there is only one single keypad selected from the plural keypads that is configured with a signal transmitting device not only capable of communicating with those of the other keypads, but also with a prime.

13. A combinatorial keyboard structure with upright standing ability, comprising:
a plurality of keypads, each being configured with at least a signal transmitting device, a first connecting mechanism being arranged at the bottom thereof, and at least a second connecting mechanism being arranged at a side thereof; and
a base, being a plate-like element with a dented space formed therein;
wherein, a keyboard structure is constructed by sequentially connecting the second connecting mechanisms of the plural keypads from one to another.

14. The combinatorial keyboard structure of claim 13, wherein both the first connecting mechanism and the second connecting mechanism are constructed as latch structures.

15. The combinatorial keyboard structure of claim 13, wherein the signal transmitting device is a device selected from the group consisting of a wired communication device and a wireless communication device.

16. The combinatorial keyboard structure of claim 13, wherein the wired communication device is a device selected from the group consisting of a USB device and a PS2 device.

17. The combinatorial keyboard structure of claim 13, wherein the signal transmitting device is enabled to link the plural keypads with one another.

18. The combinatorial keyboard structure of claim 13, wherein there is only one single keypad selected from the plural keypads that is configured with a signal transmitting device not only capable of communicating with those of the other keypads, but also with a prime.

19. The combinatorial keyboard structure of claim 13, wherein the combinatorial keyboard structure is composed of: a keyboard unit being formed by sequentially connecting the second connecting mechanisms of three keypads from one to another; and one independent keypad.

20. The combinatorial keyboard structure of claim 13, wherein the combinatorial keyboard structure is composed of: two keyboard units, each being formed by sequentially connecting the second connecting mechanisms of two keypads from one to another.

21. The combinatorial keyboard structure of claim 19, wherein the keyboard unit is connected to the independent keypad by a transmission line.

22. The combinatorial keyboard structure of claim 20, wherein the two keyboard units are connected with each other by a transmission line.
